(19) United States
(12) Patent Application Publication
(10) Pub. No.: US 2015/0349064 A1
(43) Pub. Date: Dec. 3, 2015

(54) NUCLEATION AND BUFFER LAYERS FOR GROUP III-NITRIDE BASED SEMICONDUCTOR DEVICES

(71) Applicant: Cambridge Electronics, Inc., Cambridge, MA (US)

(72) Inventors: Mohamed Azize, Medford, MA (US); Ling Xia, Somerville, MA (US); Bin Lu, Boston, MA (US); Tomas Palacios, Belmont, MA (US)

(21) Appl. No.: 14/704,269

(22) Filed: May 5, 2015

Related U.S. Application Data
(60) Provisional application No. 61/988,940, filed on May 6, 2014.

(51) Int. Cl. H01L 29/20; H01L 29/778; H01L 29/06; H01L 29/04; H01L 23/31; H01L 23/29; H01L 29/78; H01L 29/51; H01L 33/32; H01L 33/22; H01L 33/06; H01L 33/14; H01L 33/00; H01L 21/02; H01L 29/66; H01L 29/205

(52) U.S. Cl. CPC H01L 29/2003; H01L 29/205; H01L 29/7787; H01L 29/0692; H01L 29/04; H01L 23/3171; H01L 23/291; H01L 29/7849; H01L 29/518; H01L 29/517; H01L 29/51; H01L 33/32; H01L 33/22; H01L 33/06; H01L 33/14; H01L 33/0025; H01L 33/007; H01L 21/02381; H01L 21/0254; H01L 21/02458; H01L 29/66462; H01L 21/0262; H01L 21/02631

(57) ABSTRACT

A semiconductor wafer includes a substrate and at least one nucleation layer overlying the substrate. The nucleation layer includes a AlₓSi_{y}C_{z}N_{w}Oₜ composition with 0≦x≦1, 0≦y≦1, 0≦z≦1, 0≦w≦1, 0≦t≦1, and x×y>0 and with any additional impurities being less than 10% of the AlₓSi_{y}C_{z}N_{w}Oₜ composition. The semiconductor wafer also includes a buffer layer structure overlying the nucleation layer. The buffer layer structure including at least one layer having a group III nitride composition.

### BACKGROUND

Group III nitride compounds such as gallium nitride (GaN) and aluminum nitride (AlN) based compounds continue to be investigated for their use as direct bandgap semiconductors in optoelectronic devices such as light emitting diodes (LEDs) and laser diodes (LDs) and microelectronic devices such as RF devices and power transistors. Such devices potentially offer a number of important advantages. For example, advanced power electronics (PE) based on group III nitride compounds reportedly could save up to 20% of all the electricity usage in the world, or what is equivalent, providing savings in the $1 T range by 2025. Gallium Nitride (GaN)-based power transistors have been proposed as key PE components, thanks to an on-resistance that could be up to 1000 times smaller than in Si-based devices for a given breakdown voltage and higher power density with respect to conventional Si-based power devices.

Group III nitrides have typically been grown heteroepitaxially on non-native substrates and thus are subject to the well-known disadvantages attending heteroepitaxy, i.e., mismatches in lattice constants and mismatches in thermal expansion coefficients. The selection of the substrate is thought to make a significant impact on the performance of certain devices and may be influenced by a variety of factors such as cost, diameter, availability, consistency of quality, thermal and structural properties, and resistivity. There is no single conventional substrate for which all of these parameters are optimal; a compromise must be made that strikes a balance between material quality and device performance, reliability, and manufacturability.

High quality GaN layers were first achieved on sapphire substrates. For instance, conventionally, GaN-based material has been grown on a sapphire substrate by MOCVD (metal organic chemical vapor deposition). However, due to lattice and thermal expansion coefficient mismatches between the sapphire substrate and the GaN-based semiconductor, the GaN-based semiconductor grown on the sapphire substrate has a significant density of defects.

Among their other problems, sapphire substrates are relatively expensive and not well-suited for high power devices. On the other hand, the use silicon (Si) substrates instead of sapphire offers considerable cost savings because of the economies of scale associated with the large production of silicon for the semiconductor industry and the ability to use larger substrate diameters (e.g., 6, 8 and 12 inches). For instance, from a manufacturing standpoint, the use of silicon substrates would also leverage the capabilities of existing high volume silicon process services and assembly houses (e.g., wafer thinning, via technology, dicing, etc.).

Moreover, Si is a mature substrate technology, where wafers 150 mm in diameter and larger are readily available from a multiplicity of vendors for a few tens of dollars per wafer. Due to the maturity of the silicon wafer industry, substrate quality is extremely high and wafer-to-wafer consistency is generally excellent. The availability of very large-diameter, high-quality silicon substrates suggests that a GaN-on-silicon approach may be an important platform for the development of group III nitride technology.

Regardless of whether a transistor, light-emitting diode or other semiconductor device is to be fabricated, the group III nitride layers are usually epitaxially deposited over the substrate. The crystalline quality of the epitaxial group III nitride layer determines the electron trap density, and thus is a dominant factor determining the performance of the semiconductor device. In this regard, the quality of the epitaxial layer over a Si substrate is not yet fully satisfactory.

Some of the best results have been achieved by depositing a buffer layer of MN or AlGaN at a low temperature of 950° C. or less on the Si substrate, and then growing a GaN-based layer on the buffer layer at higher temperatures. The interposed buffer layer provides nucleation sites for the subsequent two-dimensional growth of a GaN buffer layer at higher temperatures and reduces dislocations due to the lattice and thermal mismatch between the substrate and the GaN-based compound, thereby improving the crystallinity and morphology of the GaN-based compound.

Nevertheless, the fabrication of group III nitride devices on Si substrates remains extremely challenging. For example, the GaN epilayers often crack upon cooling to room temperature due to the severe additive tensile stress induced by the high thermal mismatch between GaN and Si. It should be noted that cracks occur even for an epilayer thickness of about 0.5-1 μm. Therefore, to achieve thick GaN-based devices, it is important that the stress be minimized during growth to obtain crack-free films at room temperature. In addition, the blocking voltage in power transistors is limited because of the parasitic parallel conduction at the AlN/Si substrate interface.

### SUMMARY

In accordance with one aspect of the invention, a semiconductor wafer includes a substrate and at least one nucleation layer overlying the substrate. The nucleation layer includes a AlₓSi_{y}C_{z}N_{w}Oₜ composition with 0≦x≦1, 0≦y≦1, 0≦z≦1, 0≦w≦1, 0≦t≦1, and x×y>0 and with any additional impurities being less than 10% of the AlₓSi_{y}C_{z}N_{w}Oₜ composition. The semiconductor wafer also includes a buffer layer structure overlying the nucleation layer. The buffer layer structure including at least one layer having a group III nitride composition.

In accordance with another aspect of the invention, a semiconductor device includes a semiconductor wafer, a channel layer, a barrier layer and first and second electrode. The semiconductor wafer includes a substrate and at least one nucleation layer overlying the substrate. The nucleation layer includes a AlₓSi_{y}C_{z}N_{w}Oₜ composition with 0≦x≦1, 0≦y≦1, 0≦z≦1, 0≦w≦1, 0≦t≦1, and x×y>0, with any additional impurities being less than 10% of the AlₓSi_{y}C_{z}N_{w}Oₜ composition. A buffer layer structure overlies the nucleation layer. The buffer layer structure includes at least one layer having a group III nitride composition. The channel layer is disposed over the substrate. The barrier layer structure is disposed on the channel such that a laterally extending conductive channel arises which extends in a lateral direction. The laterally extending conductive channel is located in the channel layer. The first and second electrodes are electrically connected to the channel layer.

In accordance with yet another aspect of the invention, a method of forming a semiconductor structure includes forming at least one nucleation layer over a substrate. The nucleation layer includes a AlₓSi_{y}C_{z}N_{w}Oₜ composition with 0≦x≦1, 0≦y≦1, 0≦z≦1, 0≦w≦1, 0≦t≦1, and x×y>0. A buffer layer structure is formed over the nucleation layer. The buffer layer structure includes at least one layer that having a group III nitride composition.

### BRIEF DESCRIPTION OF THE DRAWINGS

FIG. 1 is a cross-sectional view of one example of a semiconductor wafer that is formed on a Si substrate.

FIG. 2—is a cross-sectional view of other examples of a semiconductor wafer formed on a Si substrate in which the nucleation layer includes a series of sublayers.

FIG. 3 is a cross-sectional view of other examples of a semiconductor wafer formed on a Si substrate in which the nucleation layer includes a series of sublayers.

FIG. 4 is a cross-sectional view of yet other examples of a semiconductor wafer formed on a Si substrate in which the buffer layer structure includes at least one 1D or 3D layer.

FIG. 5A-5E are also cross-sectional views of yet other examples of a semiconductor wafer formed on a Si substrate in which the buffer layer structure includes at least one 1D or 3D layer.

FIG. 6A-6E are cross-sectional views of yet other examples of a semiconductor wafer formed on a Si substrate in which the buffer layer structure includes at least one 1D or 3D layer.

FIGS. 7A-7B show cross-sectional views of Si substrates that are textured with mesa structures and grooves, respectively.

FIGS. 8A-8C show top views of Si substrates that include a variety of different textures.

FIG. 9 shows one example of a high electron mobility transistor (HEMT).

FIG. 10 shows one example of a light emitting diode (LED).

### DETAILED DESCRIPTION

In the following description, numerous specific details are set forth in order to provide a thorough understanding of exemplary embodiments or other examples described herein. However, it will be understood that these embodiments and examples may be practiced without the specific details. In other instances, well-known methods and procedures have not been described in detail, so as not to obscure the following description. Further, the embodiments disclosed are for exemplary purposes only and other embodiments may be employed in lieu of, or in combination with, the embodiments disclosed.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. In addition, it is appreciated that the figures provided herewith are for explanation purposes to persons ordinarily skilled in the art and that the drawings are not necessarily drawn to scale.

As discussed below, a buffer layer structure is provided on a Si or other substrate which is suitable for the subsequent formation of a group III nitride semiconductor device. Because a Si substrate may be used, the cost of manufacturing the resulting devices can be substantially reduced. Moreover, the devices can be processed in Si-compatible CMOS fabrication plants for further cost reduction. Additionally, conventional compressive stress engineering techniques that are sometimes used during the group III nitride semiconductor fabrication process of thick epilayers, which can increase the thermal resistance of the buffer layer, may not be necessary.

As used herein the term “substrate” refers to a free-standing, self-supporting structure and is not to be construed as a thin film layer that is formed on a free-standing, self-supporting structure.

As previously mentioned, one problem associated with group III nitride on Si technology arises from the lattice and thermal mismatches between the Si and the group III nitride. These mismatches cause stress that can degrade the quality of the resulting device because of the formation of cracks and the like. In some case these stresses can be reduced using the semiconductor wafers described herein.

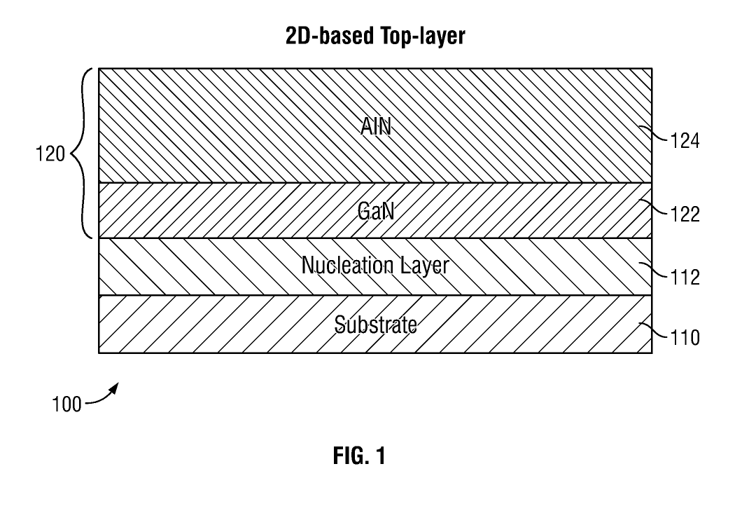

FIG. 1 is a cross-sectional view of one example of a semiconductor wafer 100 that is formed on a Si substrate 110. One or more nucleation layers 112 are formed on the substrate 110 and a buffer layer structure 120 is formed on the nucleation layer. The buffer layer structure 120 may include one or more individual buffer layers. In the particular example of FIG. 1 a single nucleation layer 112 and two buffer layers 122 and 124 are provided. The buffer layers 122 and 124 in the example of FIG. 1 comprise GaN and MN, respectively.

The nucleation layer 112 in this example may be an aluminum-silicon-carbide-oxide-nitride composition (AlxSiyCzNwOt, where 0≦x≦1, 0≦y≦1, 0≦z≦1, 0≦w≦1, 0≦t≦1, x+y+z+w+t=1 and x×y>0) based composition. In some embodiments the nucleation layer 120 may have a graded composition that varies with thickness within the layer. Such a composition has been found to provide a number of benefits. For example, the graded composition of the nucleation layer may be tailored to address the problems of lattice and thermal mismatch between the group III nitride and the Si substrate. In particular, the composition of the nucleation layer 120 can be graded to match the group III nitride lattice parameter and to introduce thermal and/or lattice compressive stress.

In general, the intrinsic stress and the electrical conductivity of the (AlxSiyCzNwOt) nucleation layer (as well the buffer layers described below) may be modulated by tuning the deposition parameters as well as the composition. For instance, the electrical conductivity of the (AlxSiyCzNwOt) nucleation layer may be modulated by tuning its composition so that the layer is relatively conducting or a relatively insulating.

The manner in which the composition of the (AlxSiyCzNwOt) nucleation layer is graded may depend on the type of device that is to be fabricated on the semiconductor wafer. For example, if the device that is to be fabricated is a high electron mobility transistor (HEMT), the nucleation layer may be graded to achieve a highly compressive, resistive layer. On the other hand, if the device being fabricated is a light emitting diode (LED), the conductivity of the (AlxSiyCzNwOt) nucleation may be tuned so that it is relatively conductive. For example, the resistivity of the nucleation layer (and the buffer layer structure) can be increased by using dopants such as Zn, Fe and C. Likewise, the conductivity of the nucleation layer (and the buffer layer structure) can be increased by using dopants such as Si, Mg, O and N.

The use of an aluminum-silicon-carbide-oxide-nitride composition as a nucleation layer is also advantageous because when MOVCD fabrication processes are employed, the aluminum-silicon-carbide-oxide-nitride composition can prevent the diffusion of organometallic materials into the substrate. Moreover, in contrast to conventional techniques that form a buffer layer on the substrate at relatively low temperatures, aluminum-silicon-carbide-oxide-nitride can be grown on the substrate at the relatively high temperatures generally used for the subsequent growth of the group III nitride layers. Accordingly, there is no need to perform thermal cycling during the growth process, thus increasing wafer growth throughput. Thus, once the nucleation layer has been formed, high temperature growth of the subsequent layers may proceed immediately.

Another advantage that arises from the use of an aluminum-silicon-carbide-oxide-nitride nucleation layer is that the parasitic conduction at the Si substrate interface can be reduced relative to the parasitic conduction that arises when an MN buffer layer is formed on the Si substrate.

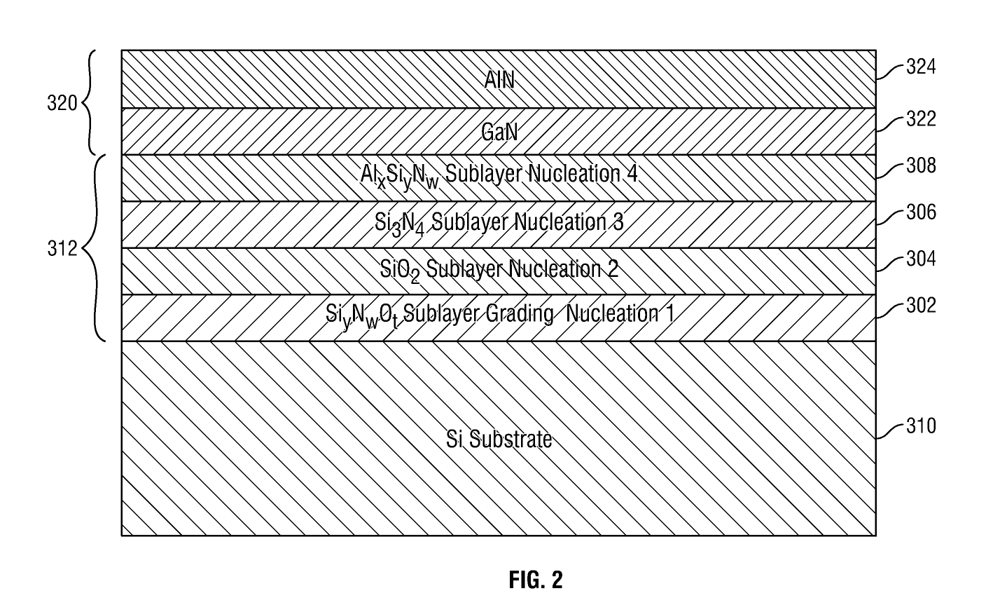

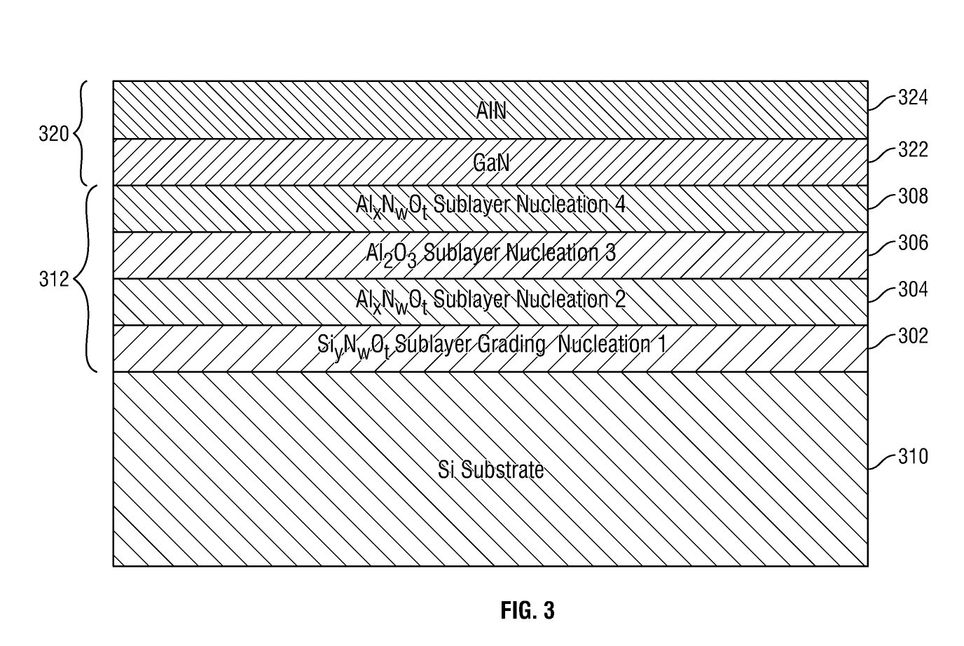

(AlxSiyCzNwOt) nucleation layer FIGS. 2-3 show cross-sectional views of additional examples of a semiconductor wafer that is formed on an Si substrate. In these examples the is graded using a series of nucleation sub-layers to provide compressive stress. In FIGS. 2-3 the (AlxSiyCzNwOt) nucleation layer 312 includes four sublayers. Specifically, a first nucleation sublayer 302 is formed on Si substrate 310, a second nucleation sublayer 304 is formed on the first nucleation layer 302, a third nucleation sublayer 306 is formed on the second nucleation sublayer 304 and, finally, a fourth nucleation sublayer 308 is formed on the third nucleation sublayer 306. The buffer layer structure 320 formed over the nucleation layer 312 may include GaN layer 322 and AlN layer 324. The buffer layer structure 320 may have a wurtzite or cubic crystal structure, for example.

In some embodiments the first nucleation sublayers 302 may be a SiYNWOt layer, which itself may be divided into two or more sublayers. In the example of FIG. 2, the first nucleation sublayer 302 may comprise the following three sublayers: Si0.17O0.83N, Si0.5O0.5N, and Si0.75O0.25N. In FIG. 3 the second, third and fourth nucleation sublayers 304, 306, and 308 may then comprise, respectively, SiO2, Si3N4, and Al0.98Si0.02N.

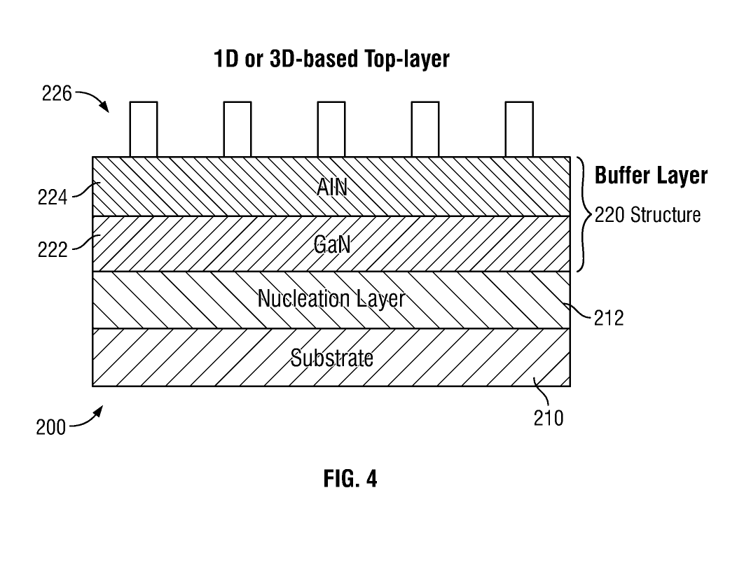

The first nucleation sublayer 312 shown in the example of FIG. 3 may also comprise three sublayers as follows: Si0.17O0.83N, Si0.5O0.5N and Si0.75O0.25N. In FIG. 4 the second, third and fourth nucleation sublayers 304, 306, and 308 may then comprise, respectively, Al0.95O0.05N, Al2O3 (1 um) and Al0.95O0.05N.

In yet other embodiments the first nucleation layer 302 comprises a first nucleation sublayer of SiyNwOt followed by a second nucleation sublayer of AlxSiyNw and, optionally, a third nucleation sublayer of AlxNwOt. In yet another embodiment the first nucleation layer 302 comprises a first nucleation sublayer of SiyNwOt followed by a second nucleation sublayer of AlxNwOt. In yet another embodiment the first nucleation layer 302 comprises a first nucleation sublayer of SiyCzNw followed by a second nucleation sublayer of AlxNwOt. Of course, the subject matter described herein may encompass a wide range of other nucleation layers other than those examples discussed above.

By way of example, in some embodiments the first nucleation sublayer 302 may have a thickness between 0.025 and 1 micron, the SiO2 nucleation sublayer 304 may have a thickness of 0.5 nm and the Si3N4 sublayer 306 may have a thickness of 3 nm. Moreover, the SiO2 nucleation sublayer 304 and the Si3N4 sublayer 306 may both be repeated to define a superlattice structure. For instance, in one embodiment the two sublayers 304 and 306 may be repeated at least 20 times.

While the substrate employed in the example of FIGS. 1-3 is a Si substrate, more generally the substrate may be any suitable resistive, conductive or semiconductor substrate such as Si, SiC, sapphire, ZnO, a group III-nitride semiconductor, or a semi-metal such as graphene or a metal such as TiN, for example. If an Si substrate is employed, in some embodiments the nucleation layer may be formed on the (111) or (001) surface of the Si substrate.

In some implementations, after preparation of the substrate using a wet and/or dry cleaning process on its surface, formation of the nucleation and buffer layers can be performed using a low cost deposition method such as sputtering, atomic layer deposition and the like[1]. The range of temperatures employed during deposition may start at about 25 C and range to upward of 900 C, for instance. If sputtering is employed, deposition parameters such as the power and bias can be tuned to adjust the intrinsic stress of the nucleation and the buffer layers. Furthermore, the tuning of these parameters may also allow adjustment of the required composition of the binary, ternary, or quaternary, etc., of the nucleation layer (which may include multiple sublayers having a graded composition). An ex-situ or in-situ post-annealing treatment may also be performed on the buffer/nucleation/substrate layers to improve the crystalline quality or activate dopants prior to any subsequent growth of a nitride-based device. In some particular implementations the annealing treatment may be performed under an ammonia, nitrogen, nitrogen and hydrogen, hydrogen, or oxygen gas with temperatures in the range of 800 C to 1200 C.

In the example of FIGS. 1-3, the semiconductor wafer 100 has a two-dimensional (i.e., planar) layer at its surface (e.g., layer 120 in FIG. 1, layer 234 in FIG. 2 and layer 324 in FIG. 3). In other embodiments, however, the semiconductor wafer 100 may have a one-dimensional (1D) or three-dimensional (3D) layer at its surface. As used herein a 1D layer is comprised of a series of 1D structures and a 3D layer is comprised of a series of 3D structures. A 1D structure refers to a quasi-one dimensional nanoscale or microscale wire characterized as having two spatial dimensions or directions that are much smaller than a third spatial dimension or direction. The wire may be oriented in the vertical direction or in a lateral direction along a surface of an underlying 2D layer. A 3D structure refers to a quasi-zero dimensional microdot or nanodot that is on a microscale or nanoscale in all three spatial dimensions or directions.

The use of a 1D and/or a 3D layer(s) can provide additional stress relief that compliments the stress relief provided by the nucleation layer. In one embodiment the total intrinsic stress in the nucleation and the buffer layer structure is compressive with a bow of less than 50 um. It should be noted that in other embodiments the total intrinsic stress in the nucleation and buffer layers may be arranged to be tensile.

FIG. 4 shows an example of a semiconductor wafer 200 that has a 1D or 3D layer at its surface. Similar to the example shown in FIG. 1, one or more nucleation layers 212 are formed on the substrate 210 and a buffer layer structure 220 that includes one or more buffer layers is formed on the nucleation layer. In the particular example of FIG. 4 a single nucleation layer 212 and three buffer layers 222, 224 and 226 are provided. As in the example of FIGS. 1-3, the nucleation layer 212 may be an aluminum-silicon-carbide-oxide-nitride based composition. In some embodiments the nucleation layer 212 has a graded composition that varies with thickness within the layer. The buffer layers 222, 224 and 226 in the example of FIG. 4 comprise GaN, AlN and AlN or GaN or AlxGal-xN[2], respectively. The buffer layers 222 and 224 are two-dimensional layers. The top-most buffer layer 226 that is formed on the two-dimensional buffer 224 defines the surface of the buffer layer structure 200 and is a 1D or 3D structure. In some embodiments the topmost buffer layer 226 may include a combination of both 1D and 3D structures.

In some cases the gaps between adjacent ones of the 1D or 3D structures in the buffer layer 226 may be partially or completely filled with a material that has a higher conductivity than the material forming the 1D or 3D buffer layer 226. For example, if the top-most buffer layer 226 is formed from MN, then the gaps may be filled, for instance, with GaN or SiC. Although the resulting layer has a two-dimensional surface made up of regions of a 1D or 3D structure alternating with the material filling the gaps between them, the resulting layer will nevertheless continue to be referred to as a 1D or 3D layer since it comprises 1D or 3D structures.

The buffer layer structure which is formed on the nucleation layer of the semiconductor wafer described herein may have a variety of different configurations and is not limited to the examples shown in FIGS. 1-4. For instance, while in FIG. 4 the 1D or 3D buffer layer is the top-most layer of the buffer layer structure 220, in other examples the 1D or 3D buffer layer may be located anywhere within the buffer layer structure 220. Moreover, in some cases two or more 1D and/or 3D buffer layers may be employed in the buffer layer structure 220.

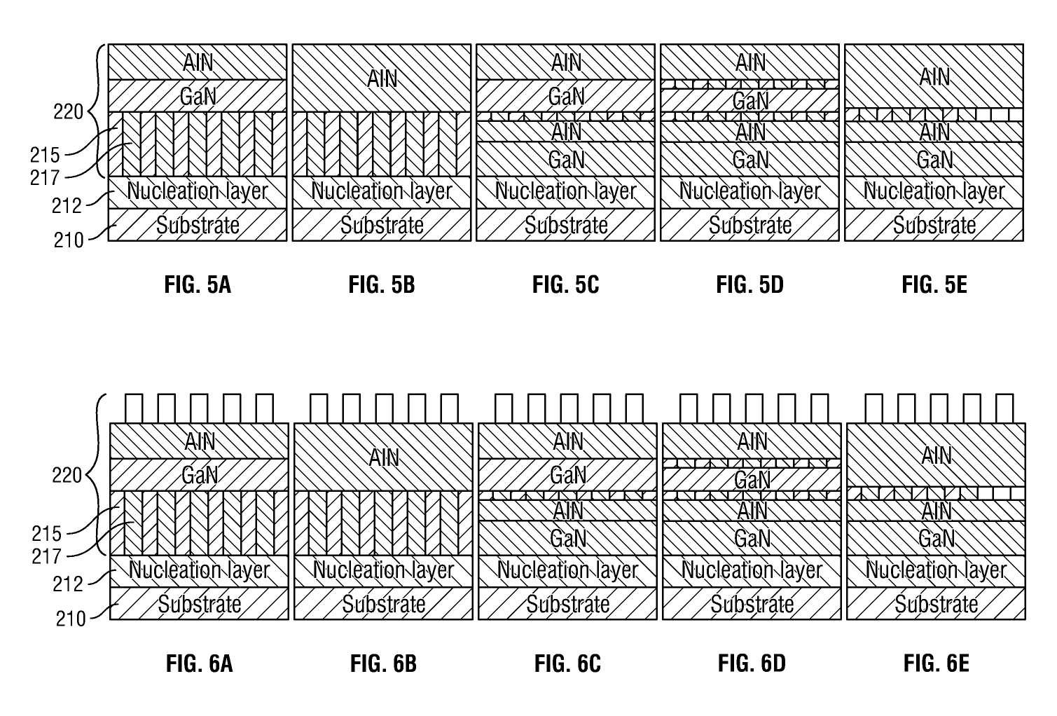

FIGS. 5a-5e show examples of semiconductor wafers 200 in which one or more 1D or 3D buffer layers are disposed within the buffer layer structure 220 and not on the top of the buffer layer structure 220. In these examples the gaps or interstices between the 1D or 3D structures 215 in the buffer layers are filled with a high conductivity material such as GaN 217. Moreover, in some of the examples the number of 2D GaN and/or AlN layers included in the buffer layer structures 200 may vary from that shown in FIG. 4. For instance, the example in FIG. 5b does not include a 2D GaN buffer layer, whereas in FIG. 5c there are two 2D GaN buffer layers (separated, in this example, by a 1D or 3D structure and an AlN layer). Likewise, the number of 1D and/or 3D buffer layers included in the buffer layer structure may vary. For instance, in FIG. 5d, the buffer layer structure includes two 1D and/or 3D buffer layers.

FIGS. 6a-6e show other examples of a semiconductor wafer 200 which include a topmost 1D or 3D buffer layer and one or more additional 1D or 3D buffer layers located within the buffer layer structure 220. As in FIGS. 5a-5e, the number and composition of individual 2D buffer layers may vary in the examples shown in FIGS. 6a-6e.

In some embodiments the individual 3D structures employed in the 3D layers described above may have a width or diameter in the range of 50 nanometers (nm) to 5000 nanometers and a length of 50 nanometers (nm) to 5000 nanometers. In addition the 3D layers may be a density of 3D structures in the range of about 1 to 100 structures per square micrometer. It will be understood that the density defines the number of 3D structures overlying a square-micrometer of the underlying layer.

In yet other embodiments the individual 1D structures employed in the 1D layers described above may have a diameter in the range of 50 nanometers (nm) to 5000 nanometers. In addition the 1D layers may be a density of 1D structures in the range of about 1 to 100 structures per square micrometer.

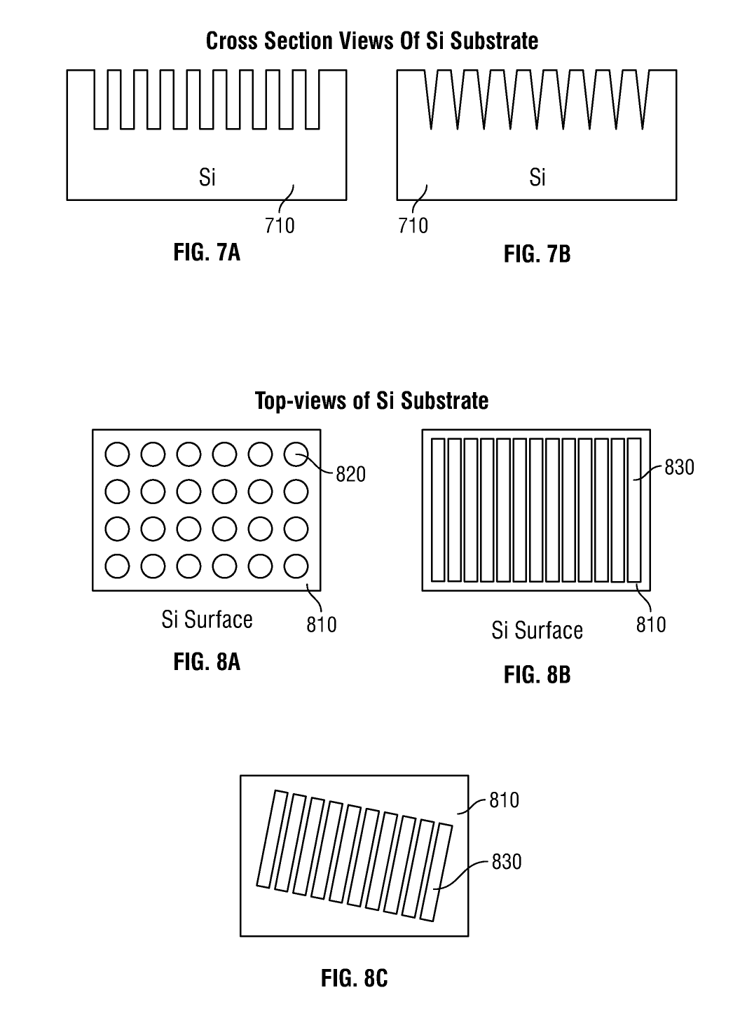

In some embodiments the Si substrate on which the nucleation layer is formed may have a textured surface to facilitate the subsequent growth of the nucleation layer. For example, the substrate surface may be textured or patterned with nanowires, nanoribbons, grooves, square mesa structures, and so on. FIGS. 7a-7b show cross-sectional views of a Si substrate 710 that are textured with mesa structures and grooves, respectively. Likewise, FIGS. 8a-8c shows a top view of a Si substrate 810 that includes a variety of different textures. The substrate in FIG. 8a includes holes 820 and the substrate in FIGS. 8b and d8c includes mesas or grooves 830. The mesas or grooves formed on the substrate in FIG. 8b extend along or perpendicular to any crystalline direction of the substrate. The mesas or grooves formed on the substrate in FIG. 8c extend along or perpendicular in any crystalline direction of the substrate.

The semiconductor wafers described above may be fabricated using an epitaxial growth process. For instance, low cost deposition techniques such as chemical vapor deposition (CVD), plasma enhanced chemical vapor deposition (PECVD), and reactive or conventional sputtering methods may be employed. The different buffer layers may be structured, for example, using a SixOyNz-based hard mask combined with dry/wet etching. As a further alternative, other epitaxial growth methods, such as molecular beam epitaxy (MBE) or atomic layer epitaxy may be used. Yet additional techniques that may be employed include, without limitation, Flow Modulation Organometallic Vapor Phase Epitaxy (FM-OMVPE), Organometallic Vapor-Phase Epitaxy (OMVPE), Hydride Vapor-Phase Epitaxy (HVPE), Atomic Layer Deposition (ALD), and Physical Vapor Deposition (PVD). Standard metallization techniques, as known in the art of semiconductor fabrication, can be used to form the electrodes.

In one example, a reactive sputtering process may be used where the metallic constituents of the semiconductor, such as gallium, aluminum and/or indium, are dislodged from a metallic target disposed in close proximity to the substrate while both the target and the substrate are in a gaseous atmosphere that includes nitrogen and one or more dopants. Other targets that may be employed may include, by way of illustration, Si, AlN, Al2O3, AlxGayN, GaN, Si3N4 and SiO2. The buffer layers may be formed by depositing Al2O3, AlN and their alloys (AlxOyN) using reactive plasma sputtering at room temperature or high temperature to provide a buffer layer structure with compressive stress and high thermal stability, i.e. melting points above 2000° C. Therefore, a low cost high breakdown voltage material such as polycrystalline Al2O3 and AlN can be used as the buffer layer(s) formed over the Si substrates. In some cases a sequence of Al2O3/graded-AlxOyN/GaN/layers may be deposited by reactive plasma sputtering on a large silicon substrate followed by a metal organic chemical vapor deposition (MOVPE) regrowth process to form a thin, high crystalline quality AlGaN/GaN heterostructure.

A wide variety of group III nitride devices may be fabricated on the semiconductor wafers described above. For purposes of illustration only and not as a limitation of the subject matter described herein, a HEMT and an LED formed on a semiconductor wafer of the type described above will be presented.

### Example 1

### HEMT

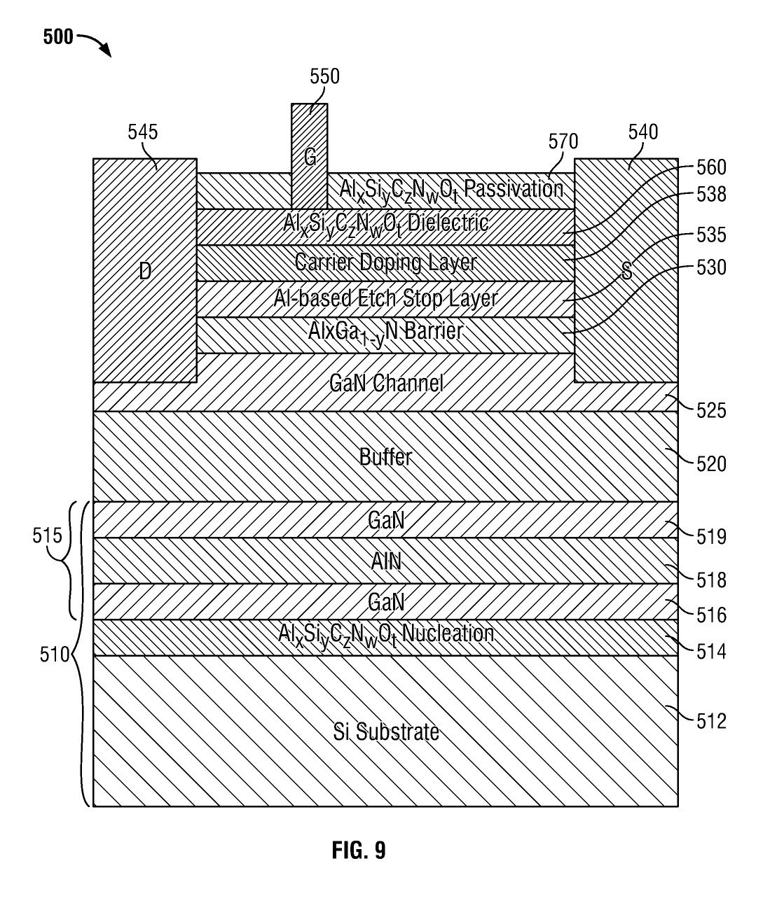

Referring to FIG. 9, an enhancement- or depletion-mode HEMT 500 is formed on a semiconductor wafer 510 that includes Si substrate 512, an aluminum-silicon-carbide-oxide-nitride nucleation layer 514 and a buffer layer structure 515 that includes, by way of example, a GaN layer 516, AlN layer 518 and a GaN layer 519. Next, a relatively thick buffer layer 520 is disposed on the surface of the semiconductor wafer 510, followed by a channel layer 525. In some embodiments, if the aluminum-silicon-carbide-oxide-nitride nucleation layer 514 contains additional impurities, those additional impurities may be less than 10% of the composition.

The buffer layer 520 in the example of FIG. 9 is comprised of semiconductor materials containing group III nitride compounds. For example, the buffer layer may comprise gallium nitride (GaN). The buffer layer 520 may also comprise a series of layers such as GaN/AlN/GaN, for example. In another example, the buffer layer may include a AlxlnyGazNw layer or multilayers of AlxSixNzOw/AlxInyGazNw, where 0≦x≦1, 0≦y≦1, 0≦z≦1, 0≦w≦1, 0≦t≦1 x+y+z+w+t=1.

The channel layer 525 may comprise a single layer or a multilayer of a group III nitride compound such as GaN or AlxInyGal-yN. A barrier layer 530 that generally has a higher bandgap than the channel layer 525 is formed on the channel 525. The barrier layer 530 may comprise a single layer or a multilayer of a group III nitride compound such as AlxInyGal-yN, for example. The barrier layer 530 gives rise to a layer of electric charge in the channel layer which is sometimes called a two-dimensional electron gas because electrons, trapped in the quantum well that results from the difference in the bandgaps, are free to move in two dimensions but are tightly confined in the third dimension.

An optional etch stop layer 535 formed from an Al-based material or the like may be disposed over the barrier layer 530. A carrier doping layer 538 is placed on top of the etch stop layer 535 to provide electrons in the channel layer 525. In one example the carrier doping layer 538 comprises InxAlyGazN (0≦x≦1, 0≦y≦1, 0≦z≦1, x+y+z=1). In one alternative embodiment, instead of a separate carrier doping layer the barrier layer 530 may include a dopant that provides electrons to the channel layer 525.

In the example of FIG. 9 a conductive source electrode 540 and a conductive drain electrode 545 are in ohmic contact with the channel layer 525. A conductive gate electrode 550 is located between the source electrode 540 and the drain electrode 545. A gate dielectric layer 560 is interposed between the gate electrode 550 and the carrier doping layer 538. The gate dielectric may comprise, for example, Al2O3, SixOy, SixNy, SixOyNz, Polytetrafluoroethylene (Teflon™), HfO2, AlN or a combination thereof. A passivation layer 570 is located on the gate dielectric layer 560. The passivation layer 570 may be a nitride, oxide or oxi-nitride single layer (such as SixNy, SixOy, AlxOyN) or a multilayer (such as SixNy/AlxOyN). In some embodiments the gate electrode 550 may be formed in a recess that is etched through the passivation layer 570 and extends, for example, to the top of the dielectric layer 560, the top of the etch stop layer 535 or the top of the barrier layer 530.

The electrical properties of the epitaxial structure shown in FIG. 9 can be modulated using any conventional acceptors or/and donors that are used to intentionally dope III-V semiconductors such as Silicon (Si), Carbon (C), Iron (Fe), Magnesium (Mg), Zinc (Zn), Beryllium (Be) or unintentionally dope III-V semiconductors such as Oxygen (O) and Hydrogen (H), which are available in the growth or deposition chamber. Furthermore, the presence of point defects (e.g. dislocations) could also be combined with intentional doping to increase the resistivity of the epitaxial structure.

Instead of the three-terminal HEMT described above, a two-terminal diode having an anode and cathode may be formed in a similar manner.

### Example 2

### LED

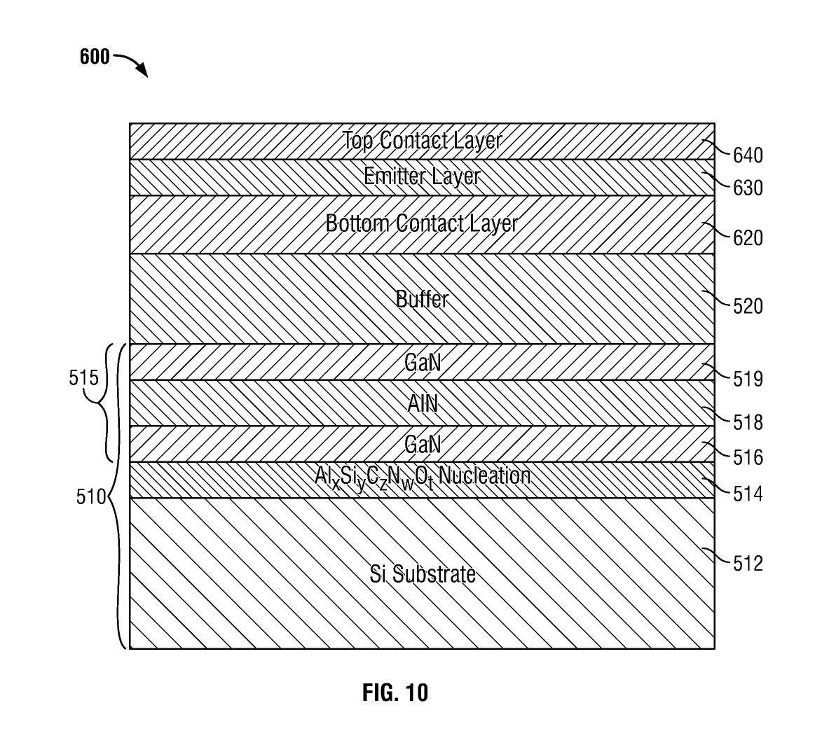

Referring to FIG. 10, a light emitting diode (LED) 600 is formed on a semiconductor wafer 510 as described above. In FIGS. 5 and 6 like elements are denoted by like reference numerals. A buffer layer 520 of e.g., GaN, is formed on the GaN layer 519.

A three layer epitaxial structure is formed on the buffer layer 520. In particular, a bottom contact layer 620 is formed on the buffer layer structure 515, an emitter layer 630 is formed on the bottom contact layer 620 and a top contact layer 640 is formed on the bottom contact layer 620. The three semiconductor layers describing the epitaxial structure may be single or multiple layers doped by conventional acceptors or/and donors, either by intentionally doping using known III-V semiconductor dopants (such as Si and Mg) or by unintentional doped using residual impurities (such as Oxygen (O) and Hydrogen (H), etc. . . . )

The bottom and top contact layers 620 and 640 may be a conductive single nitride layer or multilayer (such as n type GaN or p type GaN). In some embodiments one or both of the contact layers has a conductivity greater than 1 mS/cm and a thickness greater than 1 nm. In one embodiment the emitter layer 630 may include multiple nitride sublayers based upon multiple quantum wells (such as AlxInyGal-yN/GaN). In another embodiment the emitter layer includes multilayers of InxAlyGazN/AlxGayNz, with ≦x≦1, 0≦y≦1, 0≦z≦1, x+y+z=1.

In some embodiments, the substrate 512, the nucleation layer 514 or the GaN layer 516 may serve as either an Ohmic or Schottky contact.

The above description of illustrated examples of the present invention is not intended to be exhaustive or limited to the precise forms disclosed. While specific embodiments of, and examples for, the invention are described herein for illustrative purposes, various equivalent modifications are possible without departing from the broader spirit and scope of the present invention.

These modifications can be made to examples of the invention in light of the above detailed description. The terms used in the following claims should not be construed to limit the invention to the specific embodiments disclosed in the specification and the claims. Rather, the scope is to be determined entirely by the following claims, which are to be construed in accordance with established doctrines of claim interpretation. The present specification and figures are accordingly to be regarded as illustrative rather than restrictive.

1. A semiconductor wafer, comprising:
a substrate,
at least one nucleation layer overlying the substrate, the nucleation layer including a AlₓSi_{y}C_{z}N_{w}Oₜ composition with 0≦x≦1, 0≦y≦1, 0≦z≦1, 0≦w≦1, 0≦t≦1, and x×y>0 and with any additional impurities being less than 10% of the AlₓSi_{y}C_{z}N_{w}Oₜ composition and a buffer layer structure overlying the nucleation layer, the buffer layer structure including at least one layer having a group III nitride composition.

2. The semiconductor wafer as described in claim 1, wherein the substrate is a silicon substrate.

3. The semiconductor wafer as described in claim 1, wherein the substrate is formed from a material selected from the group consisting of silicon, sapphire, silicon carbide, ceramic, graphene, BN, ZnO, Ga₂O₃, glass and metal.

4. The semiconductor wafer as described in claim 1, wherein the nucleation layer is a continuous layer.

5. The semiconductor wafer as described in claim 1, wherein the nucleation layer is a discontinuous layer.

6. The semiconductor wafer as described in claim 1, wherein the substrate has a textured surface.

7. The semiconductor wafer as described in claim 6, wherein the textured surface is textured with a nano or micro pattern of a material selected from the group consisting of SiN, SiO₂, SiON, Al₂O₃, AlON, AlN, GaN, AlGaN, InN, InAlN, AlInGaN.

8. The semiconductor wafer as described in claim 7, wherein the nano or micro pattern includes nanowires, nanoribbons, grooves and/or square mesa structures.

9. The semiconductor wafer as described in claim 1, wherein at least one sublayer in the buffer layer structure comprises a AlₐIn_{b}Ga_{c}N layer, where 0≦a≦1, 0≦b≦1, 0≦c≦1, with a+b+c=1.

10. The semiconductor wafer as described in claim 1, wherein at least one sublayer in the buffer layer structure comprises a GaN layer disposed on the nucleation layer.

11. The semiconductor wafer as described in claim 9, wherein the buffer layer structure includes 1D structures.

12. The semiconductor wafer as described in claim 9, wherein the buffer layer structure includes 3D structures.

13. The semiconductor wafer as described in claim 9, wherein the buffer layer structure has a thickness greater than 1 nm.

14. The semiconductor wafer as described in claim 1, wherein the total stress in the nucleation and the buffer layer structure is compressive.

15. The semiconductor wafer as described in claim 1, wherein the total stress in the nucleation and the buffer layer structure is tensile.

16. The semiconductor wafer as described in claim 1, wherein the nucleation layer and the buffer layer structure include an intentional or unintentional doping material, impurity material and/or defects to control the electrical conductivity thereof.

17. The semiconductor wafer as described in claim 1, wherein the buffer layer structure has a wurtzite or cubic crystal structure.

18. A semiconductor device, comprising:
a semiconductor wafer, the semiconductor wafer including a substrate, at least one nucleation layer overlying the substrate, the nucleation layer including a AlₓSi_{y}C_{z}N_{w}Oₜ composition with 0≦x≦1, 0≦y≦1, 0≦z≦1, 0≦w≦1, 0≦t≦1, and x×y>0 and any additional impurities being less than 10% of the AlₓSi_{y}C_{z}N_{w}Oₜ composition, and a buffer layer structure overlying the nucleation layer, the buffer layer structure including at least one layer having a group III nitride composition;
a channel layer disposed over the substrate;
a barrier layer structure disposed on the channel such that a laterally extending conductive channel arises which extends in a lateral direction, the laterally extending conductive channel being located in the channel layer; and at least first and second electrodes electrically connected to the channel layer.

19. The semiconductor device as described in claim 18, wherein at least one sublayer in the buffer layer structure includes a AlₐIn_{b}Ga_{c}N composition with 0≦a≦1, 0≦b≦1, 0≦c≦1.

20. The semiconductor device as described in claim 18, wherein at least one sublayer in the buffer layer structure includes AlₓSi_{y}C_{z}N_{w}Oₜ/AlₐIn_{b}Ga_{c}N layers with 0≦x≦1, 0≦y≦1, 0≦z≦1, 0≦w≦1, 0≦t≦1, and with 0≦a≦1, 0≦b≦1, 0≦c≦1.

21. The semiconductor device as described in claim 18, wherein the nucleation and the buffer layer structure has a thickness greater than 1 nm.

22. The semiconductor device as described in claim 18, wherein the channel layer includes one or more InₐAl_{b}Ga_{c}N layers, where 0≦a≦1, 0≦b≦1, 0≦c≦1, a+b+c=1.

23. The semiconductor device as described in claim 18, wherein the barrier layer includes one or more InₐAl_{b}Ga_{c}N (0≦a≦1, 0≦b≦1, 0≦c≦1, a+b+c=1) sub-layers, at least one of the sub-layers having a wider band gap than the channel layer.

24. The semiconductor device as described in claim 18, further comprising a passivation layer disposed over the barrier layer.

25. The semiconductor device as described in claim 24, wherein the passivation layer includes a dielectric material selected from the group consisting of AlₓO_{y}, SiₓO_{y}, SiₓN_{y}, SiₓO_{y}N_{z}, polytetrafluoroethylene, HfO₂, AlN, ZrO₂, ZnO, Ga₂O₃, SiₓO_{y}N_{z}, AlₓO_{y}N_{z} or a combination thereof with (0≦x≦1, 0≦y≦1, 0≦z≦1) and with additional impurities being less than 10% of a composition of the passivation layer.

26. The semiconductor device as described in claim 25, wherein the passivation layer has a dielectric constant below 200.

27. The semiconductor device as described in claim 18, wherein the semiconductor device further comprises a gate dielectric disposed over the barrier layer and a gate electrode disposed over the gate dielectric.

28. The semiconductor device as described in claim 27, wherein the gate dielectric comprises AlₓO_{y}, SiₓO_{y}, SiₓN_{y}, SiₓO_{y}N_{z}, polytetrafluoroethylene, HfO₂, AlN, ZrO₂, ZnO, Ga₂O₃, SiₓO_{y}N_{z}, AlₓO_{y}N_{z} or a combination thereof with (0≦x≦1, 0≦y≦1, 0≦z≦1) and with any additional impurities being less than 10% of a composition of the gate dielectric.

29. The semiconductor device as described in claim 24, further comprising a carrier doping layer disposed between the channel layer and the passivation layer.

30. The semiconductor device as described in claim 29, further comprising an etch stop layer disposed between the barrier layer and the channel layer, the etch stop layer having a high etch resistance with respect to an etch resistance of the carrier doping layer.

31. The semiconductor device as described in claim 30, wherein the etch stop layer includes InₐAl_{b}Ga_{c}N (0≦a≦1, 0≦b≦1, 0≦c≦1, a+b+c=1).

32. The semiconductor device as described in claim 18, wherein the channel layer, the barrier layer and the electrodes are arranged to define a vertical or lateral device.

33. The semiconductor device as described in claim 18, wherein the first and second electrodes are source and drain electrodes, respectively, and further comprising a gate electrode disposed between the source electrode and the drain electrode.

34. The semiconductor device as described in claim 18, wherein the first and second electrodes are an anode and a cathode, respectively.

35. The semiconductor device as described in claim 18, wherein the semiconductor device further comprises a gate dielectric disposed over the channel layer and a gate electrode disposed in a recess region that extends at least though a portion of the dielectric layer.

36. The semiconductor device as described in claim 35, wherein the recess region extends through the dielectric layer and to the carrier doping layer.

37. The semiconductor device as described in claim 35, wherein the recess extends through the dielectric layer.

38. A light emitting diode (LED), comprising:
a semiconductor wafer, the semiconductor wafer including a substrate, at least one nucleation layer overlying the substrate, the nucleation layer including a AlₓSi_{y}C_{z}N_{w}Oₜ composition with 0≦x≦1, 0≦y≦1, 0≦z≦1, 0≦w≦1, 0≦t≦1, and x×y>0, and a buffer layer structure overlying the nucleation layer, the buffer layer structure including at least one layer having a group III nitride composition;
a first contact layer disposed over the substrate;
an emitter layer disposed over the first contact layer; and
a second contact layer disposed over the emitter layer.

39. The LED as described in claim 38, wherein at least one of the contact layers includes InₐAl_{b}Ga_{c}N, with 0≦a≦1, 0≦b≦1, 0≦c≦1, a+b+c=1.

40. The LED as described in claim 39, wherein the contact layer has a conductivity greater than 1 mS/cm and a thickness greater than 1 nm.

41. The LED as described in claim 38, wherein the contact layer includes multilayers of GaN/AlₐGa_{b}N_{c} with 0≦a≦1, 0≦b≦1, 0≦c≦1, a+b+c=1 and any additional impurities being less than 10% of the GaN/AlₐGa_{b}N_{c} composition

42. The LED as described in claim 38, wherein the emitter layer includes multilayers of InₐAl_{b}Ga_{c}N/AlₐGa_{b}N_{c}, with 0≦a≦1, 0≦b≦1, 0≦c≦1, a+b+c=1.

43. A method of forming a semiconductor structure, comprising:
forming at least one nucleation layer over a substrate, the nucleation layer including a AlₓSi_{y}C_{z}N_{w}Oₜ composition with 0≦x≦1, 0≦y≦1, 0≦z≦1, 0≦w≦1, 0≦t≦1, and x×y>0; and
forming a buffer layer structure over the nucleation layer, the buffer layer structure including at least one layer that includes a group III nitride composition.

44. The method as described in claim 42, wherein forming the at least one nucleation layer and the buffer layer includes depositing the at least one nucleation layer and the buffer layer at a temperature less than or equal to 900° C.

45. The method as described in claim 42, further comprising depositing the at least one nucleation layer and the buffer layer by a deposition technique selected from the group consisting of sputtering, reactive sputtering, ebeam evaporation, plasma enhanced vapor chemical deposition and atomic layer deposition.

46. The method as described in claim 42, further comprising:
forming a channel layer over the substrate;
forming a barrier layer over the channel layer; and
forming at least first and second electrodes that are electrically connected to the channel layer.

47. The method as described in claim 45, further comprising forming a passivation layer over the barrier layer.

48. The method as described in claim 46, further comprising forming a carrier doping layer that is disposed between the barrier layer and the passivation layer.

49. The method as described in claim 47, further comprising doping the carrier doping layer while it is being formed.

50. The method as described in claim 48, wherein the carrier doping layer is formed by a technique selected from the group consisting of PECVD, ALD, CVD, MOCVD, MBE and sputtering.

51. The method as described in claim 42, wherein forming the buffer layer structure includes forming a GaN layer on the nucleation layer at low temperature below 900 C.
